(19) United States
(12) Patent Application Publication
(10) Pub. No.: US 2014/0065829 A1
(43) Pub. Date: Mar. 6, 2014

(54) TRENCH FORMATION METHOD AND METHOD FOR MANUFACTURING SEMICONDUCTOR DEVICE

(71) Applicant: KABUSHIKI KAISHA TOSHIBA, Tokyo (JP)

(72) Inventors: Takayuki SAKAI, Ishikawa-ken (JP); Noriaki KATAGIRI, Hyogo-ken (JP)

(21) Appl. No.: 13/846,667

(22) Filed: Mar. 18, 2013

(30) Foreign Application Priority Data
Aug. 28, 2012 (JP) 2012-187875

(51) Int. Cl. H01L 21/3065

(52) U.S. Cl. CPC H01L 21/3065
USPC 438/702

(57) ABSTRACT

According to one embodiment, a trench formation method uses a plasma source to make a trench in a silicon substrate by alternately repeating a depositing step and an etching step. The method includes implementing the depositing step and the etching step to satisfy the formulas recited below, where a distance between the silicon substrate and a region where plasma is to be confined is x (mm), an RF power to induce the plasma is w (kW), a pressure of the depositing step is y (Pa), and a tolerable limit of fluctuation in a plane of the silicon substrate of a width of the trench to be made is z₀ (μm).

2.8w²+0.018y²−0.42wy−12w+0.91y+14≦z₀

−0.010x+0.039y+0.37≦z₀

0.00066x²+0.0064y²+0.52w²−0.018xy+0.037xw+0.0044yw−0.12x−0.048y−3.7w+6.6≦z₀

### CROSS-REFERENCE TO RELATED APPLICATIONS

This application is based upon and claims the benefit of priority from the prior Japanese Patent Application No. 2012-187875, filed on Aug. 28, 2012; the entire contents of which are incorporated herein by reference.

### FIELD

Embodiments described herein relate generally to a trench formation method and a method for manufacturing a semiconductor device.

### BACKGROUND

When manufacturing semiconductor devices such as power devices, there are cases where it is necessary to make trenches having depths of several tens of μm (microns). In particular, when manufacturing super junction-type medium-to-high voltage devices, there are cases where it is necessary to make trenches that are deep and have substantially perpendicular side surfaces. In such a case, it is necessary for the widths of the trenches to have high uniformity in the wafer plane to guarantee the characteristics of the devices that are manufactured.

### BRIEF DESCRIPTION OF THE DRAWINGS

FIGS. 1A to 1E show a method for manufacturing a semiconductor device according to an embodiment;

FIG. 2 shows a trench formation method according to the embodiment;

FIGS. 3A to 3E are cross-sectional views of processes showing the trench formation method according to the embodiment;

FIG. 4A is a plan view showing the measurement positions of the trench width of the silicon wafer; and FIG. 4B is a cross-sectional view;

FIGS. 5A to 5C and FIGS. 6A and 6B are three-dimensional graphs showing the effects of the RF power and the deposition pressure on the width WT1;

FIGS. 7A to 7C and FIGS. 8A and 8B are three-dimensional graphs showing the effects of the gap amount and the deposition pressure on the width WM;

FIGS. 9A to 9C and FIGS. 10A and 10B are three-dimensional graphs showing the effects of the deposition pressure, the gap amount, and the RF power on the width WB1;

FIG. 11 is a three-dimensional graph showing the effects of the RF power and the deposition pressure on the in-plane fluctuation of the width WT1;

FIG. 12 is a three-dimensional graph showing the effects of the gap amount and the deposition pressure on the in-plane fluctuation of the width WM;

FIG. 13 is a three-dimensional graph showing the effects of the deposition pressure, the gap amount, and the RF power on the in-plane fluctuation of the width WB1;

FIG. 14 shows the possible ranges of the RF power, the gap amount, and the deposition pressure when the in-plane fluctuation tolerable amount of WT1 is 0.3 (μm);

FIG. 15 shows the possible ranges of the RF power, the gap amount, and the deposition pressure when the in-plane fluctuation tolerable amount of WM is 0.3 (μm);

FIG. 16 shows the possible ranges of the RF power, the gap amount, and the deposition pressure when the in-plane fluctuation tolerable amount of WB1 is 0.3 (μm); and

FIG. 17 shows the possible ranges of the RF power, the gap amount, and the deposition pressure when the in-plane fluctuation tolerable amount is 0.3 (μm) for each of WT1, WM, and WB1.

### DETAILED DESCRIPTION

In general, according to one embodiment, a trench formation method uses a plasma source to make a trench in a silicon substrate by alternately repeating a depositing step and an etching step. The method includes implementing the depositing step and the etching step to satisfy formula 1, formula 2 and formula 3 recited below, where a distance between the silicon substrate and a region where plasma is to be confined is x (mm), an RF power to induce the plasma is w (kW), a pressure of the depositing step is y (Pa), and a tolerable limit of fluctuation in a plane of the silicon substrate of a width of the trench to be made is z₀ (μm).

In general, according to one embodiment, a method for manufacturing a semiconductor device includes making a trench in a silicon substrate by alternately repeating a depositing step and an etching step using a plasma source. The making of the trench includes implementing the depositing step and the etching step to satisfy formula 1, formula 2 and formula 3 recited below, where a distance between the silicon substrate and a region where plasma is to be confined is x (mm), an RF power to induce the plasma is w (kW), a pressure of the depositing step is y (Pa), and a tolerable limit of fluctuation in a plane of the silicon substrate of a width of the trench to be made is z₀ (μm).

An embodiment of the invention will now be described with reference to the drawings.

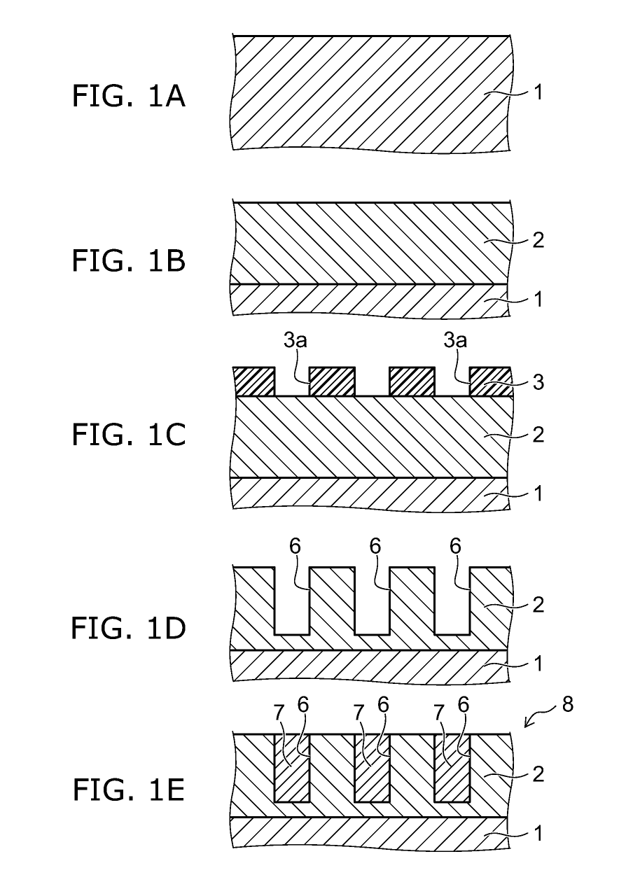

FIGS. 1A to 1E show a method for manufacturing a semiconductor device according to the embodiment.

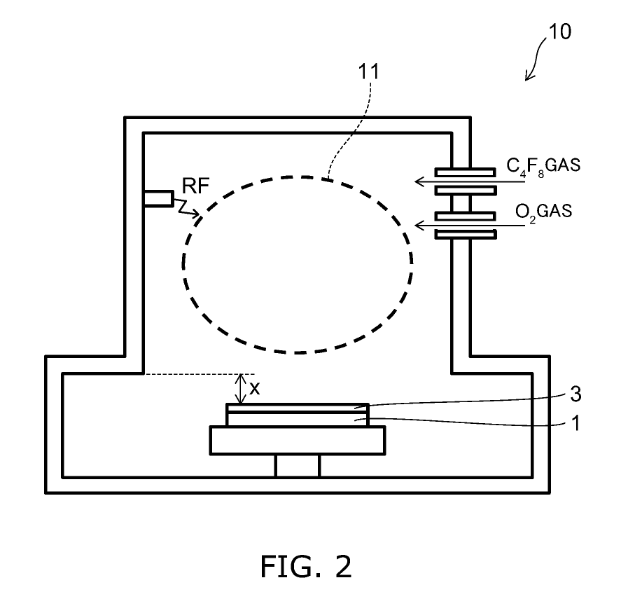

FIG. 2 shows a trench formation method according to the embodiment.

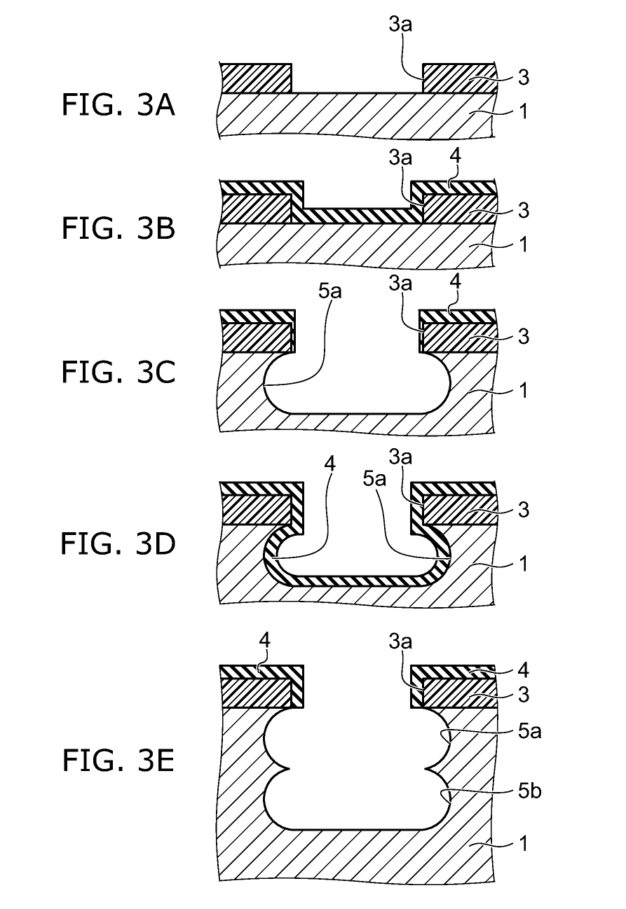

FIGS. 3A to 3E are cross-sectional views of processes showing the trench formation method according to the embodiment.

The method for manufacturing the semiconductor device according to the embodiment will now be described with reference to FIG. 1A to FIG. 3E. In the embodiment, the method for manufacturing a power semiconductor device having a super junction structure is described as an example. The description will focus on the process of the manufacturing method in which a trench is made in a silicon substrate.

First, as shown in FIG. 1A, a silicon substrate 1 is prepared. The silicon substrate 1 is, for example, a silicon wafer made of monocrystalline silicon (Si).

Then, as shown in FIG. 1B, a p-type layer 2 is formed in the upper layer portion of the silicon substrate 1.

Continuing as shown in FIG. 1C and FIG. 3A, a resist mask 3 is formed on the silicon substrate 1. Multiple openings 3a having trench configurations are periodically made in the resist mask 3. The widths of the openings 3a are, for example, 1.8 μm; and the arrangement period of the openings 3a is, for example, 8 μm. In FIGS. 3A to 3E, the p-type layer 2 (referring to FIG. 1B) is shown as a portion of the silicon substrate 1.

Then, as shown in FIG. 2, the silicon substrate 1 on which the resist mask 3 is formed is mounted in an inductively coupled plasma etching apparatus 10.

First, a depositing step is implemented using the apparatus 10. Namely, a deposition gas, e.g., a fluorocarbon gas such as C₄F₈, etc., is supplied to the apparatus 10. In this state, RF (Radio Frequency) waves of a constant output (RF power) are introduced to the apparatus 10. Thereby, a portion of the deposition gas inside the apparatus 10 is ionized; and plasma 11 is formed in a space (a confinement space) that is separated from the silicon substrate 1 by a constant distance.

As a result, as shown in FIG. 3B, a deposition film 4 is formed on the silicon substrate 1 to cover the resist mask 3. The deposition film 4 is a fluorocarbon film having a bond such as C, CF, CF₂, CF₃, etc.

Then, an etching step is implemented using the same apparatus 10. Namely, the supply of the deposition gas is stopped; and an etching gas, e.g., a gas containing fluorine such as SF₆, etc., is supplied to the apparatus 10. At this time, the RF power is maintained at a constant value. Thereby, a portion of the etching gas inside the apparatus 10 becomes the plasma 11 and is confined in a space that is separated from the silicon substrate 1 by a constant distance.

As a result, as shown in FIG. 3C, the silicon substrate 1 and the deposition film 4 are selectively removed by etching using the resist mask 3 as a mask. Thereby, a recess 5a is made in the region of the silicon substrate 1 directly under the opening 3a. At this time, the etching of the silicon substrate 1 progresses not only downward in the region directly under the opening 3a but also sideward below the resist mask 3. As a result, the recess 5a has a substantially ellipsoidal configuration spreading in the region directly under the opening 3a and at the periphery of the region directly under the opening 3a.

Then, the depositing step is implemented again. Namely, the supply of the etching gas is stopped; and the deposition gas described above is introduced to the apparatus 10. The RF power is maintained at the constant value. Thereby, as shown in FIG. 3D, the deposition film 4 is formed on the entire surface. The deposition film 4 also is formed on the inner surface of the recess 5a.

Continuing, the etching step is implemented again. Thereby, as shown in FIG. 3E, a recess 5b is made in the region directly under the recess 5a. At this time, the portion of the deposition film 4 formed on the bottom surface of the recess 5a is etched preferentially to the portion of the deposition film 4 formed on the inner side surface of the recess 5a.

Thereafter, the depositing step and the etching step described above are alternately repeated without opening the apparatus 10 to the ambient air. Thereby, the silicon substrate 1 can be progressively excavated downward by making the recesses on top of one another while using the deposition film 4 to suppress the enlargement of the recesses in the lateral direction. As a result, as shown in FIG. 1D, multiple trenches 6 are made in the p-type layer 2 of the silicon substrate 1 with depths of, for example, 50 μm. Subsequently, the resist mask 3 is removed.

At this time, the ranges of RF power w (kW), a distance x (mm), and a deposition pressure y (Pa) satisfy each of Formula 1 recited below, Formula 2 recited below, and Formula 3 recited below, where the distance between the silicon substrate 1 which is the member to be etched and the region inside the apparatus 10 where the plasma is to be confined is x (mm (millimeters)), the RF power is w (kW (kilowatts))), the pressure (the deposition pressure) of the depositing step inside the apparatus 10 is y (Pa (pascals)), and the tolerable limit of the fluctuation in the plane of the silicon substrate 1 of the width of the trench 6 to be made is z₀ (μm).

For example, an example of the apparatus 10 may have a flame body (not shown). An opening is formed on a bottom face, that is the silicon substrate 1 side face, of the flame body. In this case, an interior region of the flame body corresponds to the region where the plasma is to be confined, and the distance between the opening of the flame body and the silicon substrate 1 is x.

2.785w²+0.01788y²−0.4180wy−12.25w+0.9081y+13.61≦z₀ [Formula 1]

−0.010x+0.039y+0.37≦z₀ [Formula 2]

0.000656x²+0.00638y²+0.523w²−0.0181xy+0.0369xw+0.00436yw−0.118x−0.0485y−3.69w+6.55≦z₀ [Formula 3]

Subsequently, as shown in FIG. 1E, an n-type silicon pillar 7 is epitaxially grown inside the trench 6. Thereby, a super junction structure is formed inside the silicon substrate 1 by the p-type layer 2 and the n-type silicon pillar 7 being arranged alternately. Thus, the semiconductor device 8 is manufactured.

Effects of the embodiment will now be described.

According to the embodiment, the depositing step and the etching step are repeated at conditions to satisfy Formula 1 to Formula 3 recited above when making the trench 6 in the silicon substrate 1. Thereby, the fluctuation in the plane of the silicon substrate 1 of the width of the trench 6 can be suppressed to be not more than z₀ (μm) recited above; and the trench 6 can be made with high precision. As a result, the semiconductor device 8 having good characteristics can be manufactured stably.

The derivation process of Formula 1 to Formula 3 recited above will now be described.

Formula 1 to Formula 3 recited above are formulas determined by the following experiments.

First, similarly to the embodiment described above, a resist mask was formed on a silicon wafer. Multiple openings having trench configurations were made in the resist mask with widths of 1.8 μm and an arrangement period of 8 μm. Then, as described above, trenches were made in the upper surface of the silicon wafer which is the substrate to be etched with depths of 50 μm by repeating an etching step and a depositing step using an inductively coupled plasma etching apparatus.

At this time, the five parameters of (1) to (5) recited below were extracted as the parameters that affect the widths of the trenches.

(1) The distance between the silicon wafer and the region where the plasma is to be confined (gap amount): x (mm)

(2) The pressure of the etching step (etching pressure): u (Pa)

(3) The plasma induction RF power (RF power): w (kW)

(4) The bias power of the etching step (bias power): v (W)

(5) The pressure of the depositing step (deposition pressure): y (Pa)

Then, trenches were made in the entire surface of the silicon wafer for each combination of the parameters while varying the values of the parameters of (1) to (5) recited above. Subsequently, the widths of the trenches were measured.

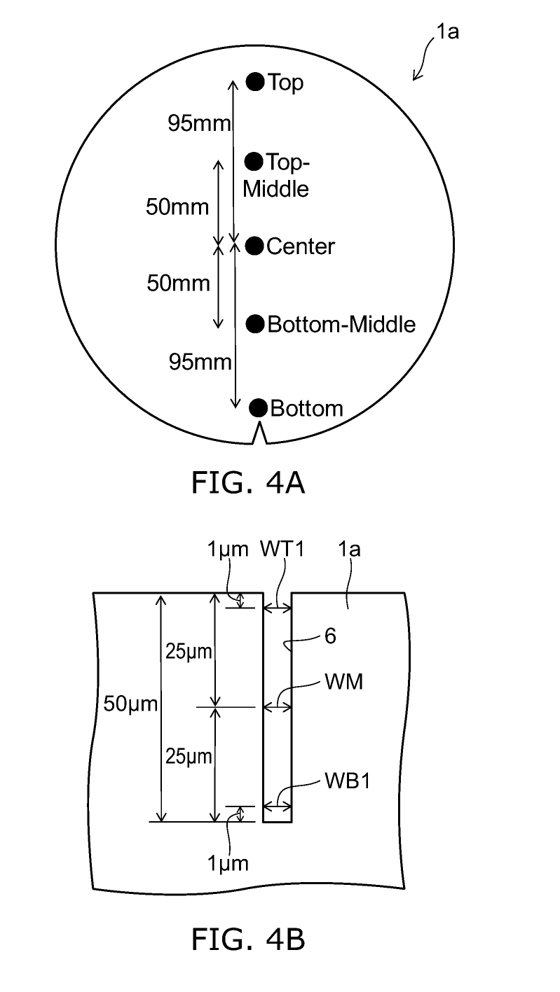

FIG. 4A is a plan view showing the measurement positions of the trench width of the silicon wafer; and FIG. 4B is a cross-sectional view.

As shown in FIG. 4A, the measurement of the trench width was performed at the following five points on a silicon wafer 1a.
Top
Center
Bottom
Top-Middle (middle portion between Top and Center)
Bottom-Middle (middle portion between Bottom and Center)

As shown in FIG. 4B, the measurement of the width of each of the trenches was performed at three points in the depth direction.
The width at a position 1 μm below the upper end of the trench: WT1
The width at the depth-direction central portion of the trench: WM
The width at a position 1 μm above the lower end of the trench: WB1

In other words, for one silicon wafer, the width of the trench was measured at five points in the plane and three points in the depth direction for a total of fifteen points. Then, the difference of the maximum value and the minimum value of the five points in the plane described above were calculated for each of the widths WT1, WM, and WB1; and the differences were taken to be the in-plane fluctuation for each of the widths WT1, WM, and WB1. As a result, it was ascertained that the RF power and the deposition pressure greatly affect the in-plane fluctuation of the width WT1; the gap amount and the deposition pressure greatly affect the in-plane fluctuation of the width WM; and the gap amount, the deposition pressure, and the RF power greatly affect the in-plane fluctuation of the width WB1.

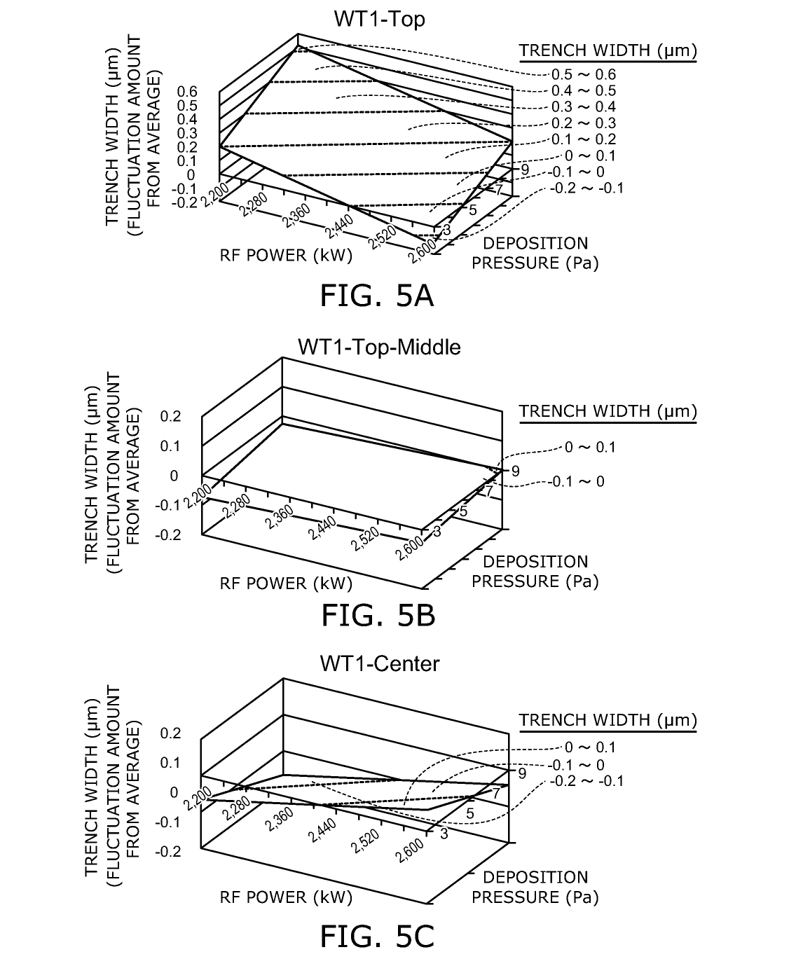

FIGS. 5A to 5C and FIGS. 6A and 6B are three-dimensional graphs showing the effects of the RF power and the deposition pressure on the width WT1, where the first axis is the RF power, the second axis is the deposition pressure, and the third axis is the measured value of the width WT1.

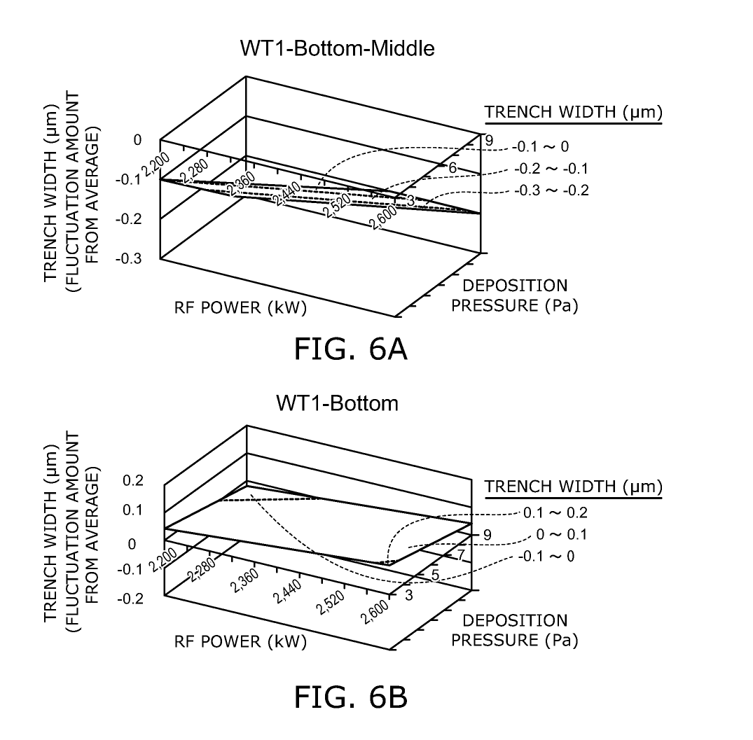

FIGS. 7A to 7C and FIGS. 8A and 8B are three-dimensional graphs showing the effects of the gap amount and the deposition pressure on the width WM, where the first axis is the gap amount, the second axis is the deposition pressure, and the third axis is the measured value of the width WM.

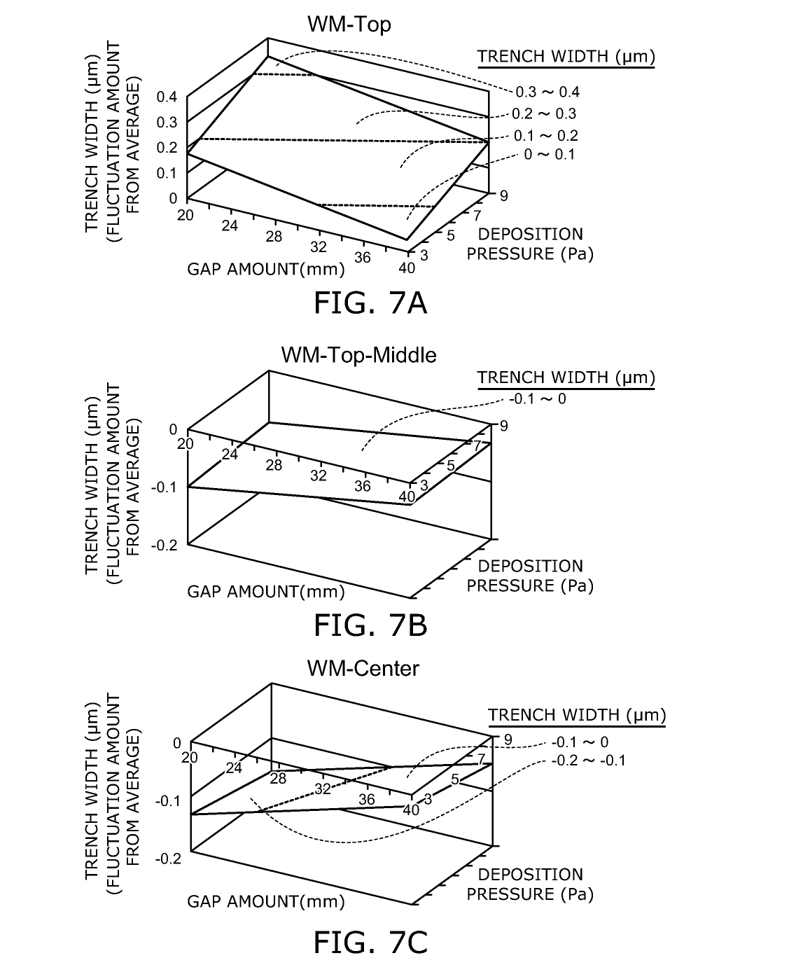

FIGS. 9A to 9C and FIGS. 10A and 10B are three-dimensional graphs showing the effects of the deposition pressure, the gap amount, and the RF power on the width WB1, where the first axis is the deposition pressure, the second axis is the gap amount, and the third axis is the RF power.

The value of the trench width of the third axis in each of FIG. 5A to FIG. 8B and the value of the trench width illustrated by the contours in each of FIG. 9A to FIG. 10B are the differences from the average of the measured values of the five points in the plane described above.

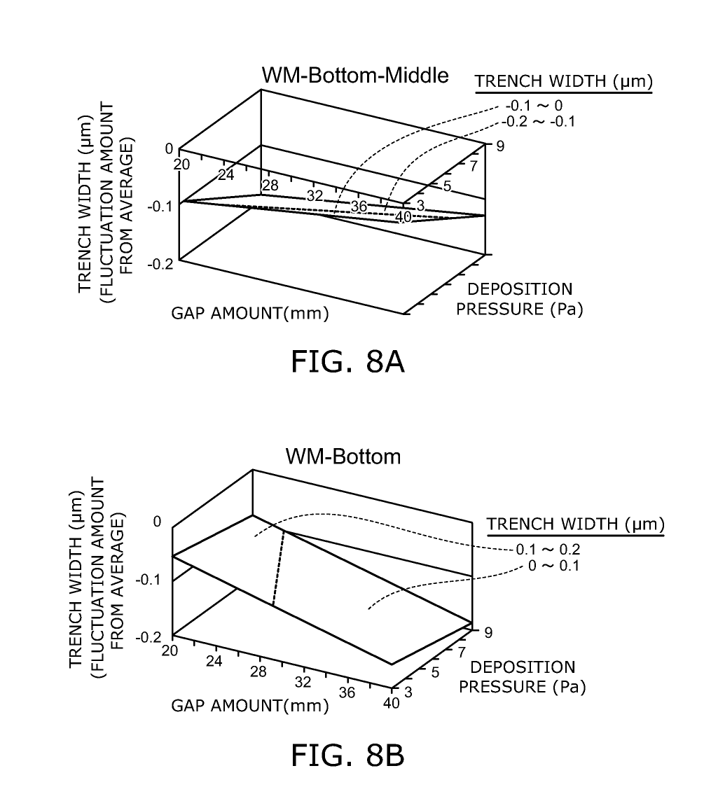

FIG. 11 is a three-dimensional graph showing the effects of the RF power and the deposition pressure on the in-plane fluctuation of the width WT1, where the first axis is the RF power, the second axis is the deposition pressure, and the third axis is the in-plane fluctuation of the width WT1.

The in-plane fluctuation of the width WT1 of the third axis of FIG. 11 is the difference between the maximum value and the minimum value of the five measured values of the width WT1 shown in FIGS. 5A to 5C and FIGS. 6A and 6B for each of the combinations of the RF power and the deposition pressure.

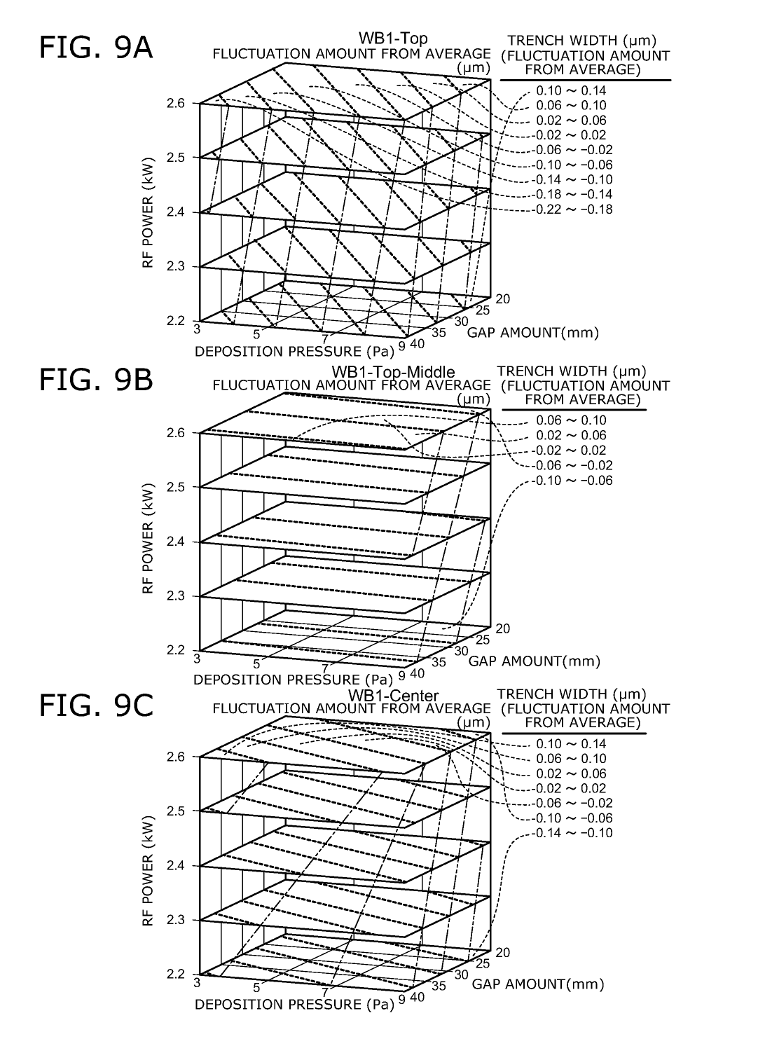

FIG. 12 is a three-dimensional graph showing the effects of the gap amount and the deposition pressure on the in-plane fluctuation of the width WM, where the first axis is the gap amount, the second axis is the deposition pressure, and the third axis is the in-plane fluctuation of the width WM.

The in-plane fluctuation of the width WM of the third axis of FIG. 12 is the difference between the maximum value and the minimum value of the five measured values of the width WM shown in FIGS. 7A to 7C and FIGS. 8A and 8B for each of the combinations of the gap amount and the deposition pressure.

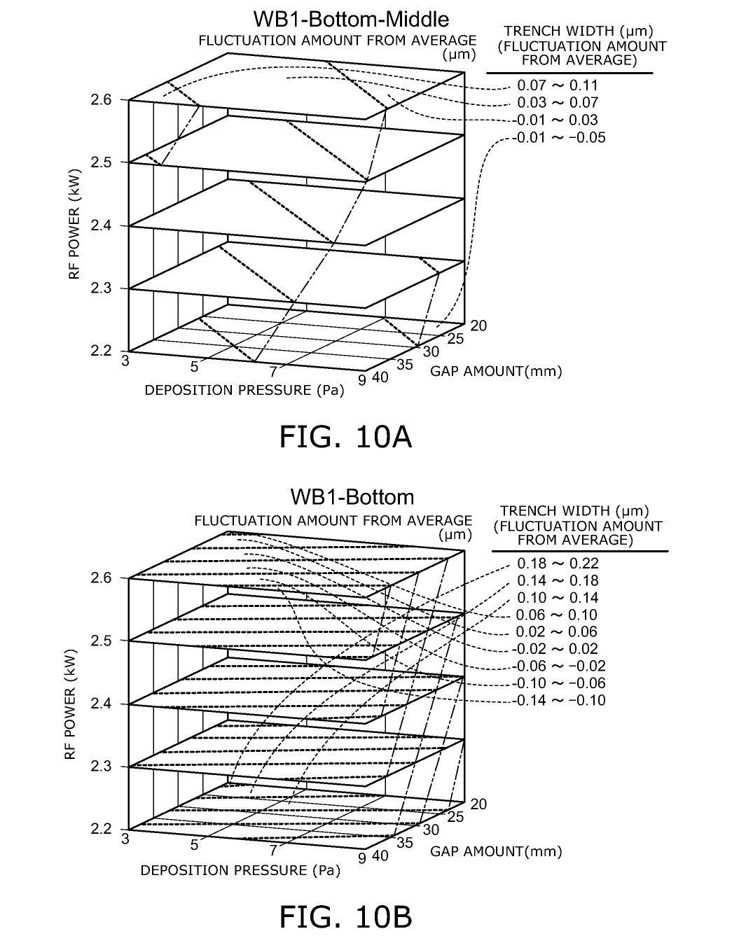

FIG. 13 is a three-dimensional graph showing the effects of the deposition pressure, the gap amount, and the RF power on the in-plane fluctuation of the width WB1, where the first axis is the deposition pressure, the second axis is the gap amount, and the third axis is the RF power.

The in-plane fluctuation of the width WB1 illustrated by the contours in FIG. 13 is the difference between the maximum value and the minimum value of the five measured values of the width WB1 shown in FIGS. 9A to 9C and FIGS. 10A and 10B for each of the combinations of the gap amount, the deposition pressure, and the RF power.

As shown in FIG. 11, it was ascertained that the in-plane fluctuation of the width WT1 has a minimum value relating to the RF power and the deposition pressure.

The relationship between the RF power, the deposition pressure, and the in-plane fluctuation of the width WT1 shown in FIG. 11 can be approximated by the quadric surface of Formula 4 recited below, where the RF power is w (kW), the deposition pressure is y (Pa), and the in-plane fluctuation is z (μm).

z=2.785w²+0.01788y²−0.4180wy−12.25w+0.9081y+13.61 [Formula 4]

As shown in FIG. 12, the in-plane fluctuation of the width WM decreased as the gap amount increased and the deposition pressure decreased.

The relationship between the gap amount, the deposition pressure, and the in-plane fluctuation of the width WM shown in FIG. 12 can be approximated by the first order plane of Formula recited below, where the gap amount is x (mm), the deposition pressure is y (Pa), and the in-plane fluctuation is z (μm)

z=−0.01003x+0.03929y+0.3692 [Formula 5]

As shown in FIG. 13, it was ascertained that the in-plane fluctuation of the width WB1 depends on the RF power and has a minimum value relating to both gap amount and the deposition pressure.

The relationship of the in-plane fluctuation of the width WB1 with the gap amount, the deposition pressure, and the RF power shown in FIG. 13 can be approximated by the quadric surface of Formula 6 recited below.

z=0.0006558x²+0.006377y²+0.5227w²−0.01813xy+0.03686xw+0.00436yw−0.1178x−0.04847y−3.692w+6.551 [Formula 6]

According to Formula 4 recited above, the ranges of the RF power w and the deposition pressure y such that the fluctuation amount z of the width WT1 is not more than z₀ are the range satisfying Formula 7 recited below.

2.785w²+0.01788y²−0.4180wy−12.25w+0.9081y+13.61≦z₀ [Formula 7]

From Formula 5 recited above, the values of the gap amount x and the deposition pressure y such that the fluctuation amount z of the width WM is not more than z₀ are in the range of Formula 8 recited below.

−0.01003x+0.03929y+0.3692≦z₀ [Formula 8]

From Formula 6 recited above, the values of the gap amount x, the deposition pressure y, and the RF power w such that the fluctuation amount z of the width WB1 is not more than z₀ are in the range of Formula 9 recited below.

0.0006558x²+0.006377y²+0.5227w²−0.01813xy+0.03686xw+0.00436yw−0.1178x−0.04847y−3.692w+6.551≦z₀ [Formula 9]

Summarizing the description recited above, the in-plane fluctuation z at all of the widths WT1, WM, and WB1 of the trenches can be the value z₀ or less by the RF power w, the gap amount x, and the deposition pressure y having values satisfying Formulas 7 to 9 recited above. Formulas 7 to 9 recited above correspond to Formulas 1 to 3 recited above.

Also, significant figures of Formulas 1 to 3 to be needed for a form accuracy of a trench are two. However, it is preferably that a significant figure of Formula 1 is four, a significant figure of Formula 2 is two, a significant figure of Formula 3 is three. Thereby, each of the above parameters can be calculated in one higher significant figure than a significant figure to be needed for a form accuracy of a trench, and a trench having high form accuracy can be formed certainly.

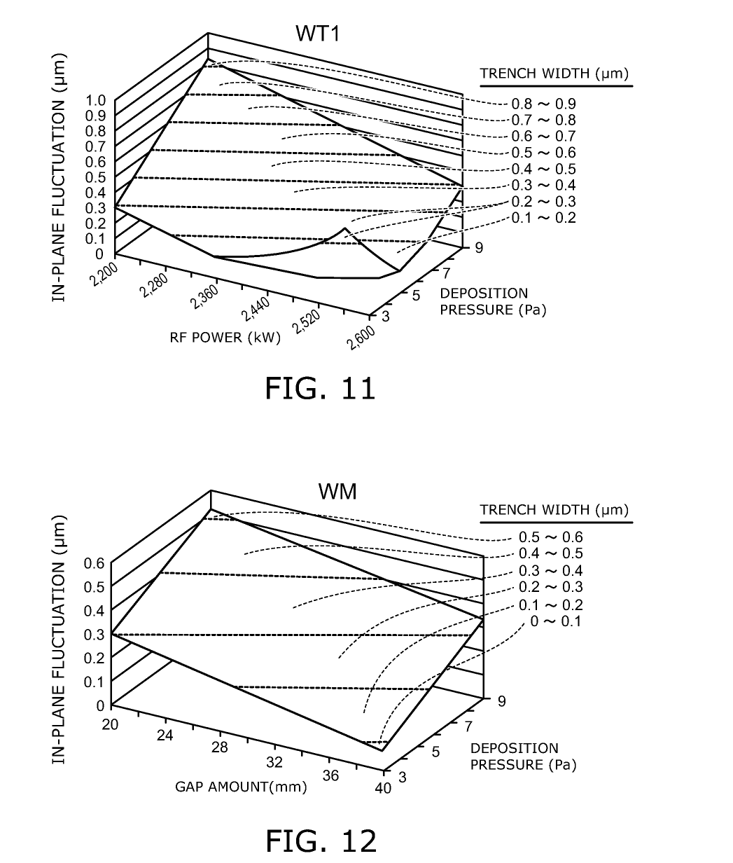

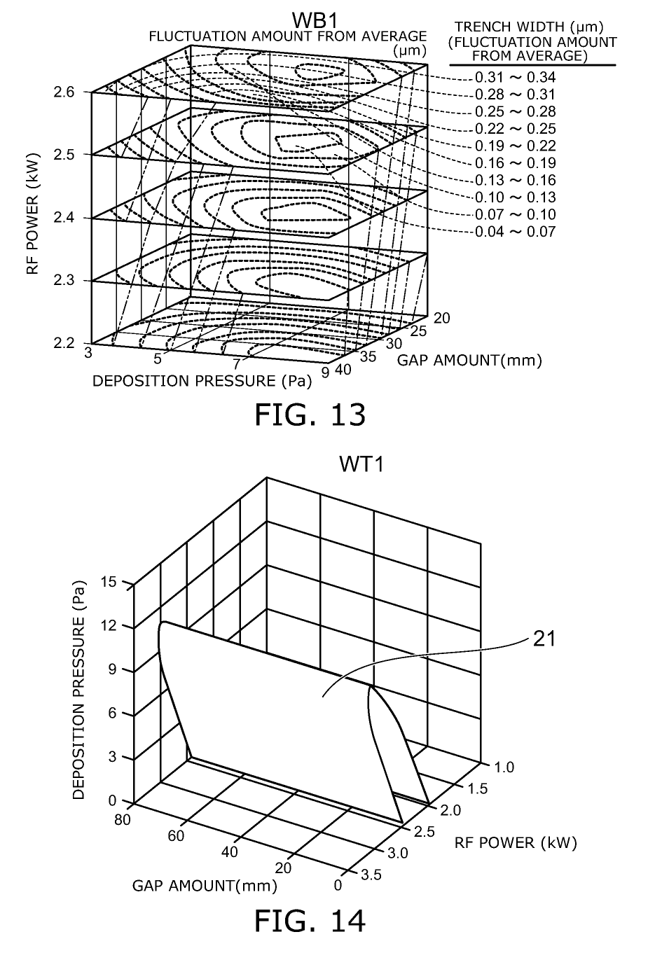

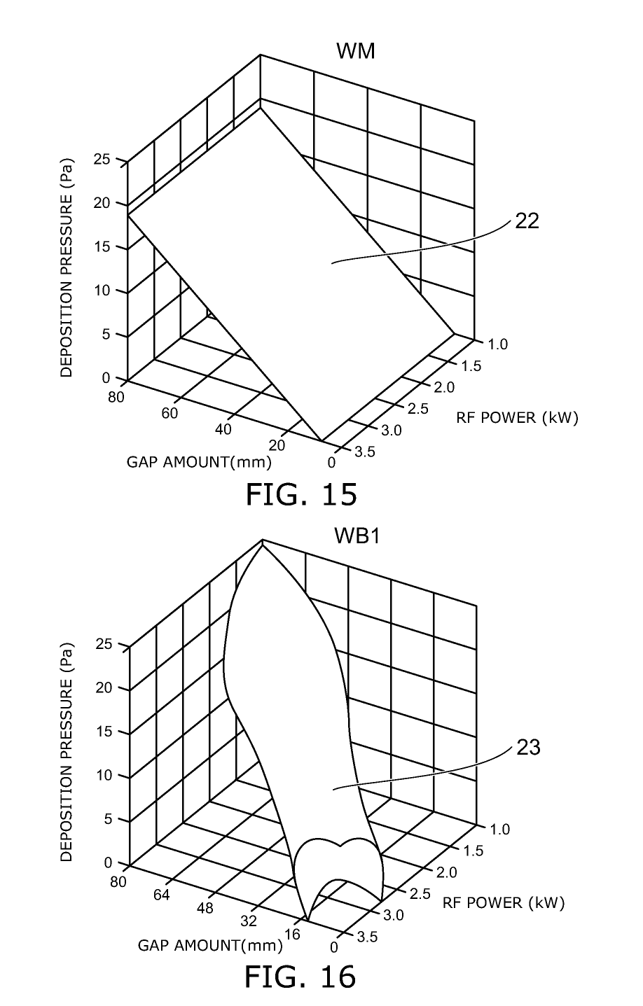

Formulas 7 to 9 recited above represent the possible regions of the RF power w, the gap amount x, and the deposition pressure y in wxy space with respect to the tolerable in-plane fluctuation z0 of the trench width. As an example, the possible regions of the RF power w, the gap amount x, and the deposition pressure y when z0=0.3 (μm) are shown in FIG. 14, FIG. 15, and FIG. 16 for the width WT1, the width WM, and the width WB1, respectively.

FIG. 14 shows the possible ranges of the RF power, the gap amount, and the deposition pressure when the in-plane fluctuation tolerable amount of WT1 is 0.3 (μm), where the first axis is the RF power, the second axis is the gap amount, and the third axis is the deposition pressure.

FIG. 15 shows the possible ranges of the RF power, the gap amount, and the deposition pressure when the in-plane fluctuation tolerable amount of WM is 0.3 (μm), where the first axis is the RF power, the second axis is the gap amount, and the third axis is the deposition pressure.

FIG. 16 shows the possible ranges of the RF power, the gap amount, and the deposition pressure when the in-plane fluctuation tolerable amount of WB1 is 0.3 (μm), where the first axis is the RF power, the second axis is the gap amount, and the third axis is the deposition pressure.

As shown in FIG. 14, for any gap amount, the in-plane fluctuation of the width WT1 is not more than 0.3 (μm) in the region inside a curved surface 21 that curves in a U-shape.

As shown in FIG. 15, for any RF power, the in-plane fluctuation of the width WM is not more than 0.3 (μm) in the region where the deposition pressure is less than a plane 22.

As shown in FIG. 16, the in-plane fluctuation of the width WB1 is not more than 0.3 (μm) in the region inside a cylindrical curved surface 23.

Then, the combinations of the RF power, the gap amount x, and the deposition pressure y that satisfy all of Formulas 7 to 9 recited above are the combinations for which the in-plane fluctuation of all of the widths WT1, WM, and WB1 is not more than 0.3 (μm), which corresponds to the overlapping portion of the regions shown in FIGS. 14 to 16.

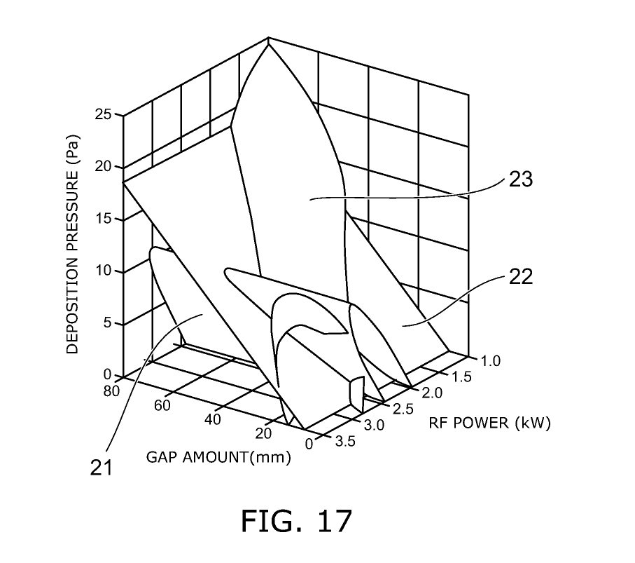

FIG. 17 shows the possible ranges of the RF power, the gap amount, and the deposition pressure when the in-plane fluctuation tolerable amount is 0.3 (μm) for each of WT1, WM, and WB1, where the first axis is the RF power, the second axis is the gap amount, and the third axis is the deposition pressure.

FIG. 17 shows the overlapping portion of the regions shown in FIG. 14 to FIG. 16. In other words, the in-plane fluctuation at all of the widths WT1, WM, and WB1 can be 0.3 (μm) or less by the combinations of the values of the RF power w, the gap amount x, and the deposition pressure y being combinations plotted in the interior of the overlapping portion shown in FIG. 17.

Although an example is illustrated in the embodiments described above in which a power semiconductor device having a super junction structure is manufactured, the invention is not limited thereto and is favorably applicable to methods for manufacturing semiconductor devices in which a deep trench is made in a silicon substrate. For example, the invention is applicable to form a trench in MEMS (Micro Electro Mechanical System) device and so on. Although an example is illustrated in the embodiments described above in which the silicon substrate is a silicon wafer, this is not limited thereto. It is sufficient for at least a portion of the silicon substrate to be made of silicon where the trench is made.

According to the embodiments described above, a trench formation method and a method for manufacturing a semiconductor device having highly uniform patterning dimensions in the plane can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A trench formation method using a plasma source to make a trench in a silicon substrate by alternately repeating a depositing step and an etching step, the method comprising:
implementing the depositing step and the etching step to satisfy the formulas recited below, where a distance between the silicon substrate and a region where plasma is to be confined is x (mm), an RF power to induce the plasma is w (kW), a pressure of the depositing step is y (Pa), and a tolerable limit of fluctuation in a plane of the silicon substrate of a width of the trench to be made is z₀ (μm).
2.8w²+0.018y²−0.42wy−12w+0.91y+14≦z₀
−0.010x+0.039y+0.37≦z₀
0.00066x²+0.0064y²+0.52w²−0.018xy+0.037xw+0.0044yw−0.12x−0.048y−3.7w+6.6≦z₀

2. The method according to claim 1, wherein a fluorocarbon gas is used as a deposition gas of the depositing step.

3. The method according to claim 2, wherein the fluorocarbon gas is C₄F₈.

4. The method according to claim 1, wherein a gas containing fluorine is used as an etching gas of the etching step.

5. The method according to claim 4, wherein the etching gas is SF₆.

6. The method according to claim 1, wherein the depositing step and the etching step are performed by the same apparatus.

7. A method for manufacturing a semiconductor device, comprising making a trench in a silicon substrate by alternately repeating a depositing step and an etching step using a plasma source,
the making of the trench including implementing the depositing step and the etching step to satisfy the formulas recited below, where a distance between the silicon substrate and a region where plasma is to be confined is x (mm), an RF power to induce the plasma is w (kW), a pressure of the depositing step is y (Pa), and a tolerable limit of fluctuation in a plane of the silicon substrate of a width of the trench to be made is z₀ (μm).
2.8w²+0.018y²−0.42wy−12w+0.91y+14≦z₀
−0.010x+0.039y+0.37≦z₀
0.00066x²+0.0064y²+0.52w²−0.018xy+0.037xw+0.0044yw−0.12x−0.048y−3.7w+6.6≦z₀

8. The method according to claim 7, wherein a fluorocarbon gas is used as a deposition gas of the depositing step.

9. The method according to claim 8, wherein the fluorocarbon gas is C₄F₈.

10. The method according to claim 7, wherein a gas containing fluorine is used as an etching gas of the etching step.

11. The method according to claim 10, wherein the etching gas is SF₆.

12. The method according to claim 7, wherein the depositing step and the etching step are performed by the same apparatus.

13. The method according to claim 7, further comprising:
forming a first-conductivity-type layer in an upper layer portion of the silicon substrate; and
forming a silicon pillar of a second conductivity type in an interior of the trench,
the trench being made in the first-conductivity-type layer.

14. The method according to claim 7, wherein a plurality of the trenches is periodically arranged.

15. The method according to claim 14, wherein a super junction structure is formed of the first-conductivity-type layer and the silicon pillar.
